(19) United States
(12) Patent Application Publication
(10) Pub. No.: US 2021/0375736 A1
(43) Pub. Date: Dec. 2, 2021

(54) MULTICORE SUBSTRATE

(71) Applicant: QUALCOMM Incorporated, San Diego, CA (US)

(72) Inventors: Joan Rey Villarba BUOT, Escondido, CA (US); Zhijie WANG, San Diego, CA (US); Aniket PATIL, San Diego, CA (US); Hong Bok WE, San Diego, CA (US); Kuiwon KANG, San Diego, CA (US)

(21) Appl. No.: 17/332,962

(22) Filed: May 27, 2021

Related U.S. Application Data
(60) Provisional application No. 63/031,881, filed on May 29, 2020.

(51) Int. Cl. H01L 23/498; H01L 21/48

(52) U.S. Cl. CPC H01L 23/49822; H01L 21/4857; H01L 23/49827; H01L 23/49816

(57) ABSTRACT

Various package configurations and methods of fabricating the same are disclosed. In some aspects, a package may include a core layer and a first layer directly attached to a first side of the core layer, where a first device is embedded in the first layer. A second layer can be directly attached to a second side of the core layer opposite the first side, where a second passive device is embedded in the second layer. A first build-up layer can be directly attached to the first layer opposite the core layer, and a second build-up layer can be directly attached to the second layer opposite the core layer.

### CROSS-REFERENCE TO RELATED APPLICATION

The present application for patent claims the benefit of U.S. Provisional Patent Application No. 63/031,881 entitled “MULTICORE SUBSTRATE,” filed May 29, 2020, assigned to the assignee hereof, and expressly incorporated herein by reference in its entirety.

### FIELD OF DISCLOSURE

This disclosure relates generally to substrates, and more specifically, but not exclusively, to multicore substrates.

### BACKGROUND

Integrated circuit packages are being widely used today in electronic circuits. For example, artificial intelligence (AI), Compute, and Server packages are widely used today. However, these packages conventional have thick laminate core in the substrates due to stiffness requirement for these types of packages. This thick core has an impact on power delivery from board to logics on semiconductor die in the package. There are existing conventional solutions such as die side capacitor (DSC), land side capacitor (LSC), and embedded passive substrate (EPS). Unfortunately, these conventional approaches still they have many limitations, such as: DSC—lateral connectivity, not good for power delivery network; LSC—far away from die logics due to thick core and more layers of fiberglass impregnated with resin (prepreg), less effective; and EPS—better than LSC, but still away from logic as substrate total layers are 8-20 for these products.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a package comprises: a core layer; a first layer directly attached to a first side of the core layer; a second layer directly attached to a second side of the core layer, the second side of the core layer opposite the first side of the core layer; a first build-up layer directly attached to the first layer opposite the core layer; a second build-up layer directly attached to the second layer opposite the core layer; a first passive device in the first layer; and a second passive device in the second layer.

In another aspect, an apparatus comprises a package substrate includes a core structure; a first embedded passive substrate (EPS) layer directly attached to a first side of the core structure, wherein a first passive device is embedded in the first layer; a second EPS layer directly attached to a second side of the core structure opposite the first side of the core structure, wherein a second passive device is embedded in the second EPS layer; a first build-up layer directly attached to the first layer opposite the core structure; and a second build-up layer directly attached to the second EPS layer opposite the core structure.

In still another aspect, a package comprising: means for insulating; first means for embedding directly attached to a first side of the means for insulating; second means for embedding directly attached to a second side of the means for insulating, the second side of the means for insulating opposite the first side of the means for insulating; a first means for support directly attached to the first means for embedding opposite the means for insulating; a second means for support directly attached to the second means for embedding opposite the means for insulating; a first passive device in the first means for embedding; and a second passive device in the second means for embedding.

In still another aspect, a method for manufacturing a package, the method comprises: providing a core layer; forming a first layer directly on a first side of the core layer; forming a second layer directly on a second side of the core layer, the second side of the core layer opposite the first side of the core layer; embedding a first passive device in the first layer; embedding a second passive device in the second layer; forming a first build-up layer directly on the first layer opposite the core layer; and forming a second build-up layer directly on the second layer opposite the core layer.

In still another aspect, a non-transitory computer-readable medium comprising instructions that when executed by a processor cause the processor to perform a method comprises: providing a core layer; forming a first layer directly on a first side of the core layer; forming a second layer directly on a second side of the core layer, the second side of the core layer opposite the first side of the core layer; embedding a first passive device in the first layer; embedding a second passive device in the second layer; forming a first build-up layer directly on the first layer opposite the core layer; and forming a second build-up layer directly on the second layer opposite the core layer.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates a package in accordance with at least one aspect of the disclosure;

FIGS. 2A and B illustrate additional packages in accordance with at least one aspect of the disclosure;

FIGS. 3A-L illustrate a method for manufacturing a package in accordance with at least one aspect of the disclosure;

FIGS. 4A-C illustrate additional methods for manufacturing a package in accordance with at least one aspect of the disclosure;

FIG. 5 illustrates an additional package configuration in accordance with at least one aspect of the disclosure;

FIG. 6 illustrates an exemplary mobile device in accordance with at least one aspect the disclosure; and

FIG. 7 illustrates various electronic devices that may be integrated with any of the aforementioned methods, devices, semiconductor devices, integrated circuits, die, interposers, packages, or package-on-packages (PoPs) in accordance with at least one aspect of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The methods, apparatus, and systems disclosed herein mitigate shortcomings of the conventional methods, apparatus, and systems, as well as other previously unidentified needs. Examples herein provide closer connectivity to semiconductor die than obtainable from embedded passive substrates, land side capacitors, or die side capacitors, better pitch placement than non-pre-packaged/embedded components, high density configurations, structural symmetry, better mechanical stability, and do not require a ball grid array de-pop process for land side passives. Examples described herein have significant improvements over conventional approaches including, but not limited to: allowing capacitors to be attached closer to die core for better power distribution network (PDN) performance; better warpage management through balanced embedded passive structure/location at opposite sides of the substrate core; enabling package size reduction by removal of die side passives; avoiding ball grid array (BGA) pin removal or de-pop due to land side passives; help electrical and mechanical stability; flexibility in multilayer ceramic capacitor (MLCC) selection as compared to land side passives due to height restriction from BGA ball height. It should be understood that while the example herein may illustrate implementation in a BGA configuration, the scope of the disclosure is not limited to packages/devices with a BGA but may also be implemented or applied to similar configurations such as a Land Grid Array (LGA) configuration (e.g., for server devices).

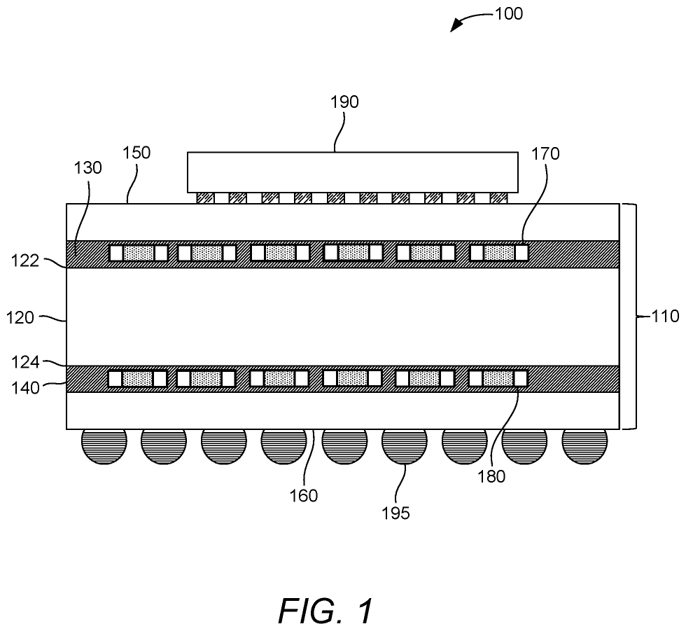

FIG. 1 illustrates an exemplary package in accordance with at least one aspect of the disclosure. As shown in FIG. 1, a package 100 may include a substrate 110 comprising: a core layer 120; a first layer 130 directly attached to a first side 122 of the core layer 120; a second layer 140 directly attached to a second side 124 of the core layer 120 opposite the first side 122 of the core layer 120; a first build-up layer 150 directly attached to the first layer 130 opposite the core layer 120; and a second build-up layer 160 directly attached to the second layer 140 opposite the core layer 120. The package 100 may also include a first plurality of passive devices 170 in the first layer 130; and a second plurality of passive devices 180 in the second layer 140. While multiple passive devices are shown, it should be understood that a single passive device may be used in each of the device layers.

In addition, package 100 may further include a semiconductor die 190 on the first build-up layer 150 opposite the first layer 130; a plurality of solder balls 195 on the second build-up layer 160 opposite the second layer 140. Also, the first plurality of passive devices 170 and the second plurality of passive devices 180 may be symmetrically located on opposite sides of the core layer 120 allowing closer connectivity to other devices, such as on-board inductors; the core layer 120 may comprise a plurality of laminate layers (including insulating and metal layers), such as 10 or 16, for example; the first layer 130 and/or the second layer 140 may comprise one or a plurality of dielectric layers, such as 2; the first build-up layer 150 and/or the second build-up layer 160 may comprise a plurality of thin dielectric layers, such as 2 layers, which may be a prepreg layer, Ajinomoto build-up film (ABF), resin coated copper (RCC) build-up film or other suitable material, and one or more metallization structures (not illustrated) to reduce the die to passive z-height or routing distance. The details of example first and second buildup layers are discussed in greater detail in the following disclosure and related drawings. The package may be incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

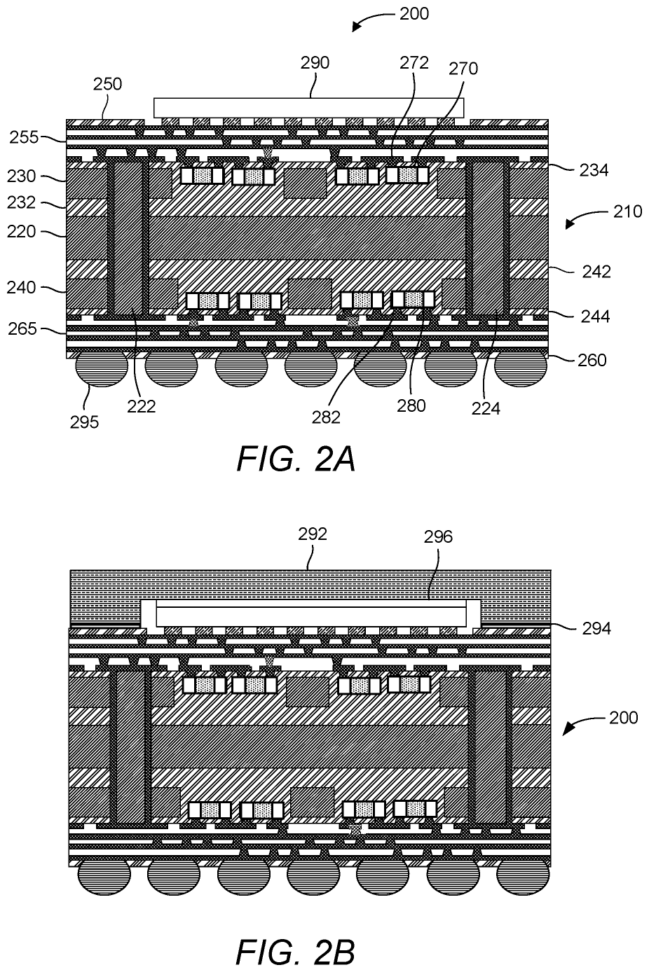

FIGS. 2A and B illustrate additional exemplary packages in accordance with at least one aspect of the disclosure. As shown in FIG. 2A, a package 200 (e.g., package 100) may include a substrate 210 comprising: a core layer 220; a first layer 230 having dielectric layers 232 and 234 on opposite sides and being directly attached to a first side of the core layer 220 by dielectric layer 232; a second layer 240 having dielectric layers 242 and 244 on opposite sides and being directly attached to a second side of the core layer 220 by dielectric layer 242 opposite the first side of the core layer 220; a first build-up layer 250 directly attached to the first layer 230 by dielectric layer 234 opposite the core layer 220; a second build-up layer 260 directly attached to the second layer 240 by dielectric layer 244 opposite the core layer 220. The first layer 230 also includes a first plurality of passive devices 270; and the second layer 240 includes a second plurality of passive devices 280. In addition, first build-up layer 250 may include a first metallization structure 255 (e.g., a redistribution structure or layer) coupled to the first plurality of passive devices 270 by a first plurality of vias 272. The second build-up layer 260 may include a second metallization structure 265 coupled to the second plurality of passive devices 280 by a second plurality of vias 282. A first plated through hole (PTH) 222 and a second PTH 224 can be used to electrically couple the first metallization 255 to the second metallization 265 and/or any metal layers or structures between (e.g., in core 220, first layer 230, and/or second layer 230). The illustration of FIG. 2A can be considered a bare die package configuration, for example.

As shown in FIG. 2B, the package 200 may also include a lid 292 to protect the die 290 and attached to the package 200 with a first adhesive layer 294 and to the die 290 with a second adhesive layer 296 for a lidded package configuration, for example. The first adhesive layer 294 may be a thermal adhesive and the second adhesive layer 296 may be thermal insulator when the lid 292 is configured as a heat sink, for example. While multiple passive devices are shown, it should be understood that a single passive device may be used in each of the device layers.

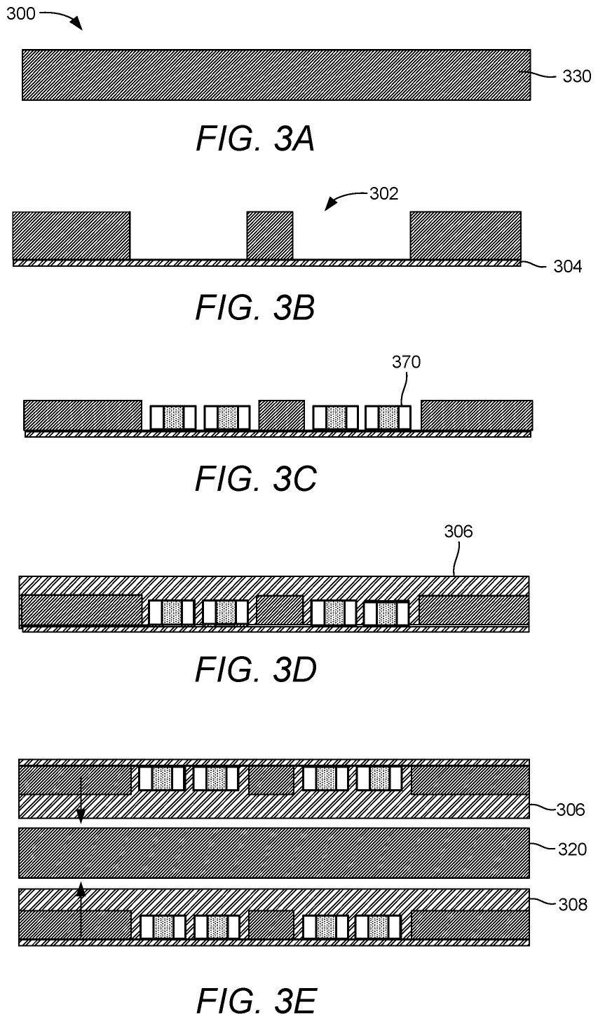

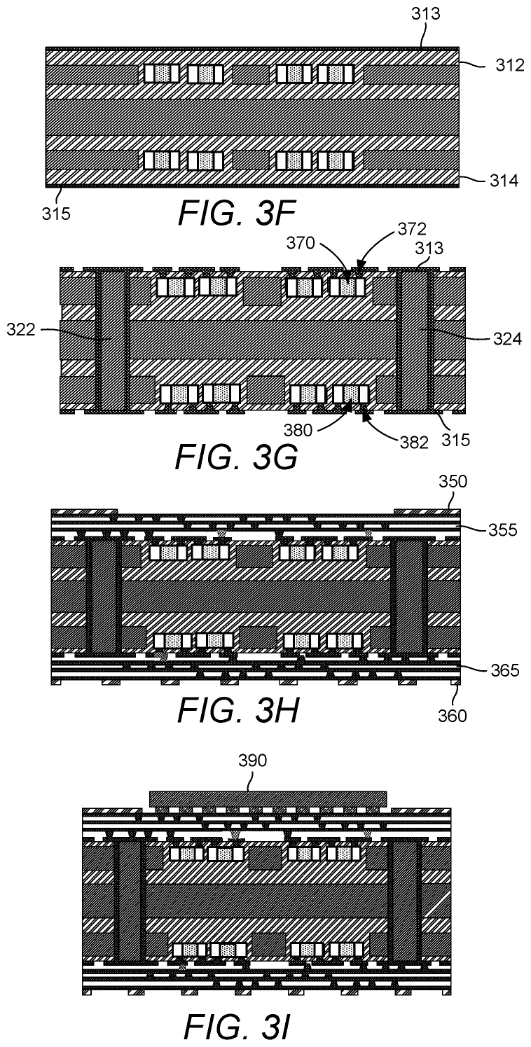

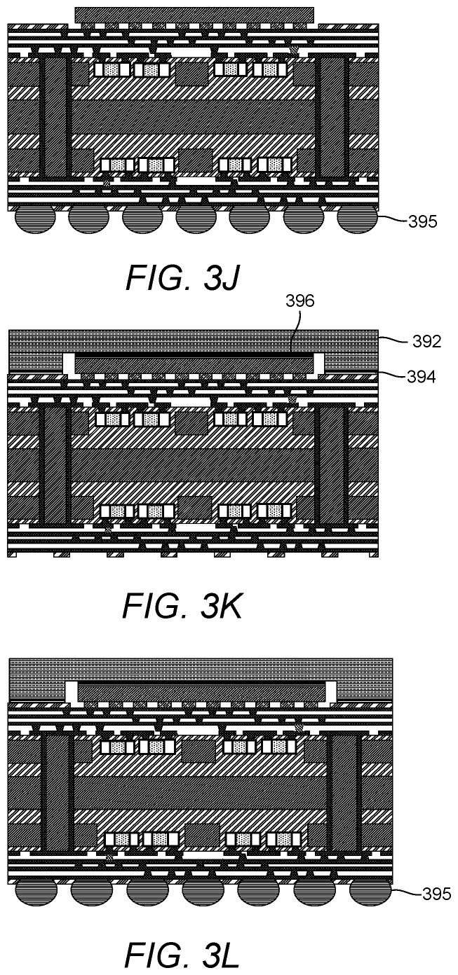

FIGS. 3A-L illustrate an exemplary partial method for manufacturing a package in accordance with at least one aspect of the disclosure. As shown in FIG. 3A, the partial method 300 may begin with providing or forming a first layer 330 and stripping material, such as copper, from the first layer 330. As shown in FIG. 3B, the partial method 300 may continue with forming one or more cavities 302 and applying a tape 304. As shown in FIG. 3C, the partial method 300 may continue with attaching a first plurality of passive devices 370 in each of the cavities 302. As shown in FIG. 3D, the partial method 300 may continue with laminating at least one layer of a first dielectric 306. It should be understood that the process may be used to create a second layer. As shown in FIG. 3E, the partial method 300 may continue with attaching/laminating the at least one layer of the first dielectric 306 to a core layer 320 and attaching/laminating at least one layer of a second dielectric 308 to the core layer 320 opposite dielectric 306. As shown in FIG. 3F, the partial method 300 may continue with detaching the tape 304, cleaning the structure, laminating at least one layer of a third dielectric 312 with a metal layer 313 (e.g., copper foil) and laminating at least one layer of a fourth dielectric 314 with a metal layer 315 (e.g., copper foil). As shown in FIG. 3G, the partial method 300 may continue with forming a first plate through hole (PTH) 322 and a second PTH 324. Additionally, a first plurality of vias 372 may be formed to couple the first plurality of passive devices 370 to the metal layer 313. Likewise, a second plurality of vias 382 may be formed to couple a second plurality of passive devices 380 to the metal layer 315. As shown in FIG. 3H, the partial method 300 may continue with forming a first build-up layer 350 (e.g., with an Ajinomoto build-up film (ABF)) with a first metallization structure 355 and forming a second build-up layer 360 with a second metallization structure 365. As shown in FIG. 3I, the partial method 300 may continue with attaching a semiconductor die 390 (integrated circuit, logic circuit, or similar) to the first build-up layer 350. For a bare die configuration, the partial method 300 may conclude as shown in FIG. 3J with attachment of solder balls 395 on the second build-up layer 360. Alternatively, for a lidded package configuration, the partial method 300 may continue as shown in FIG. 3K with attachment of a lid 392 including applying a first adhesive layer 394 and a second adhesive layer 396. For the lidded die configuration, the partial method 300 may conclude as shown in FIG. 3L with attachment of solder balls 395 on the second build-up layer 360.

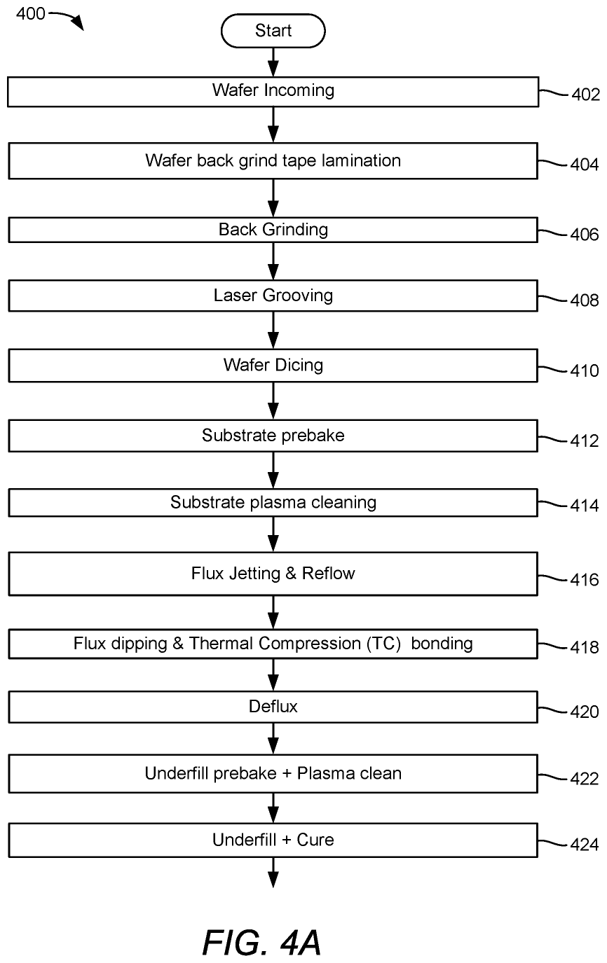

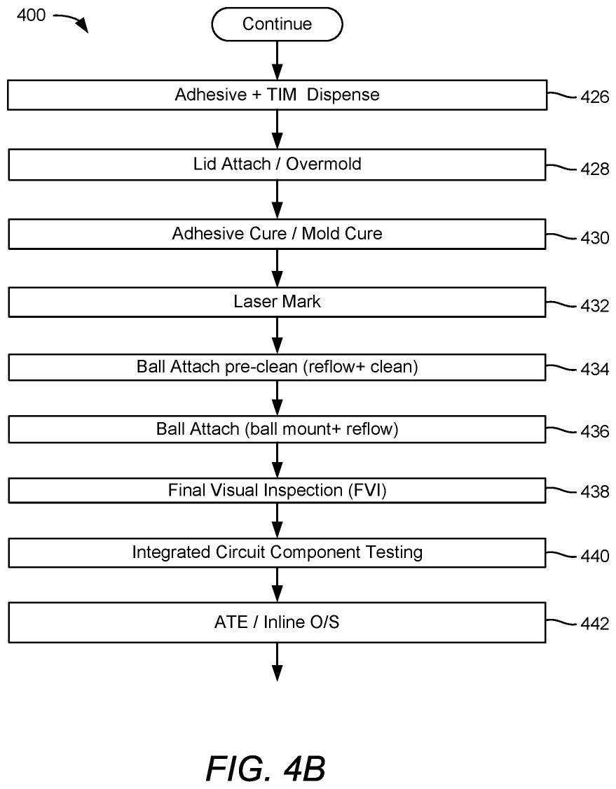

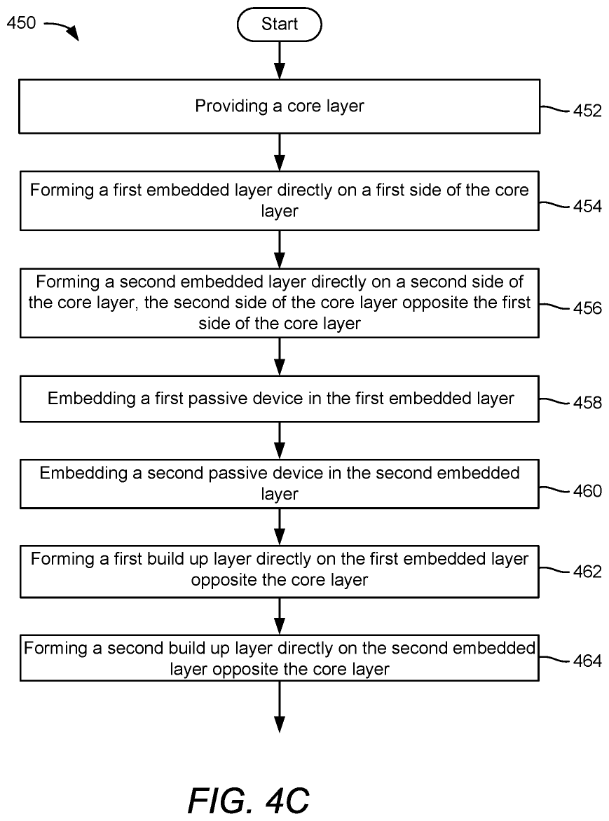

FIGS. 4A-C illustrate additional exemplary methods for manufacturing a package in accordance with at least one aspect of the disclosure. As shown in FIG. 4A, a partial method 400 (e.g., method 300) may being in block 402 with receiving an incoming wafer. The partial method 400 may continue in block 404 with back grinding the wafer and laminating with tape. The partial method 400 may continue in block 406 with additional back grinding. The partial method 400 may continue in block 408 with laser grooving. The partial method 400 may continue in block 410 with dicing the wafer. The partial method 400 may continue in block 412 with prebaking the current substrate structure. The partial method 400 may continue in block 414 with plasma cleaning the current substrate structure. The partial method 400 may continue in block 416 with flux jetting and reflow. The partial method 400 may continue in block 418 with flux dipping and thermal compression (TC) bonding. The partial method 400 may continue in block 420 with defluxing. The partial method 400 may continue in block 422 with prebaking an underfill and another process of plasma cleaning. The partial method 400 may continue in block 424 with adding additional underfill and curing underfill.

As shown in FIG. 4B, the partial method 400 may continue in block 426 with applying or dispensing an adhesive and thermal interface material. The partial method 400 may alternatively continue in block 428 with attaching a lid or over molding, such as for a lidded die configuration. The partial method 400 may continue in block 430 with curing the adhesive and/or mold. The partial method 400 may continue in block 432 with marking by a laser. The partial method 400 may continue in block 434 with pre-cleaning for attaching solder balls with a reflow and clean process. The partial method 400 may continue in block 436 with attaching the solder balls with a mount and reflow process. The partial method 400 may continue in block 438 with a final visual inspection (FVI) process. The partial method 400 may continue in block 440 with an integrated circuit component testing (e.g., ICOS) process. The partial method 400 may conclude in block 442 with automatic testing equipment (ATE) and/or an Inline O/S process.

As shown in FIG. 4C, the partial method 450 may begin in block 452 with providing a core layer. The partial method 450 may continue in block 454 with forming a first layer directly on a first side of the core layer. The partial method 450 may continue in block 456 with forming a second layer directly on a second side of the core layer, the second side of the core layer opposite the first side of the core layer. The partial method 450 may continue in block 458 with embedding a first passive device in the first layer. The partial method 450 may continue in block 460 with embedding a second passive device in the second layer. The partial method 450 may continue in block 462 with forming a first build-up layer directly on the first layer opposite the core layer. The partial method 450 may conclude in block 464 with forming a second build-up layer directly on the second layer opposite the core layer.

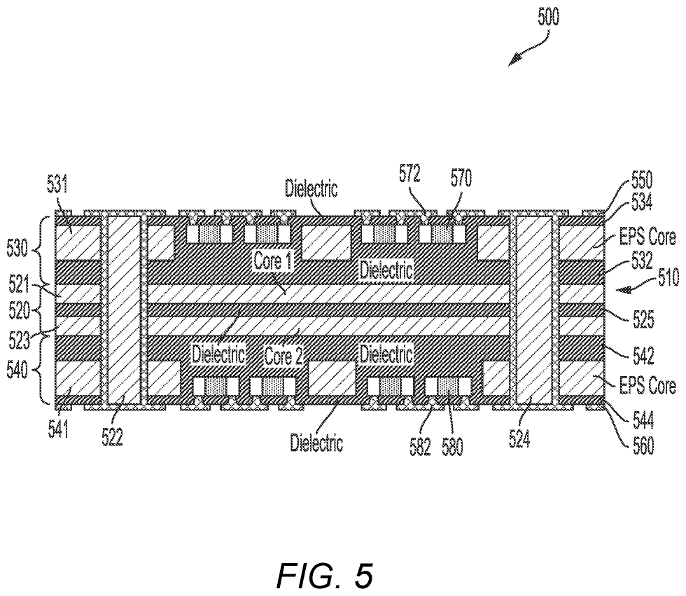

FIG. 5 illustrates an additional package configuration in accordance with at least one aspect of the disclosure. As shown in FIG. 5, a package 500 may include a substrate 510 including core structure 520, which may include a first core layer 521 and a second core layer 523 separated by a center dielectric 525 disposed between the first core layer 521 and a second core layer 523. It will be appreciated that the core structure may only contain a single core layer, such as the illustrated in relation to FIGS. 1-3L. Additionally, it will be appreciated that the term “core structure” could be used interchangeably with “core layer” and the core layer, as used herein may comprise multiple core layers, Accordingly, even if illustrated as a single layer, it will be understood that the various aspects disclosed herein contemplate configurations comprising one or more layers.

Referring back to FIG. 5, a first embedded passive substrate (EPS) layer 530 has an EPS core 531 and dielectric layers 532 and 534 on opposite sides of the EPS core 531 and is directly attached to a first side of the first core layer 521 by dielectric layer 532. A second EPS layer 540 has an EPS core 541 with dielectric layers 542 and 544 on opposite sides of the EPS core 541 and is directly attached to a second side of the second core layer 523 by dielectric layer 542 opposite the first side of the first core layer 521. A first build-up layer 550 is directly attached to the first EPS layer 530 by dielectric layer 534 opposite the first core layer 521. The first build-up layer 550 is illustrated only as a single layer for convenience, however, the first build-up layer 550, may include multiple layers and in some aspects may be similar to any of the previously described buildup layers. A second build-up layer 560 is directly attached to the second EPS layer 540 by dielectric layer 544 opposite the second core layer 523. The second build-up layer 560 is illustrated only as a single layer for convenience, however, the first build-up layer 550, may include multiple layers and in some aspects may be similar to any of the previously described buildup layers. The first EPS layer 530 also includes a first plurality of passive devices 570; and the second EPS layer 540 includes a second plurality of passive devices 580. In addition, first build-up layer 550 may include a first metallization structure (e.g., a redistribution structure or layer, not illustrated, but similar to the configurations discussed above). The first build-up layer 550 is coupled to the first plurality of passive devices 570 by a first plurality of vias 572. The second build-up layer 560 may include a second metallization structure (e.g., a redistribution structure or layer, not illustrated, but similar to the configurations discussed above). The second build-up layer 560 is coupled to the second plurality of passive devices 580 by a second plurality of vias 582. A first plated through hole (PTH) 522 and a second PTH 524 can be used to electrically couple the first build-up layer 550 to the second build-up layer 560 and/or any metal layers or structures between (e.g., in the first core layer 521, the second core layer 523, the first EPS layer 530, and/or the second EPS layer 540). The illustration of FIG. 5 illustrates a portion of a package configuration, for example, the metallization layers, die, lid, solder balls, and/or other components may be added to form the package, in accordance with the various aspects disclosed herein.

Accordingly, it will be appreciated that the various aspects disclosed herein can include an apparatus (e.g., 100, 200, 500) comprising a package substrate (110, 210, 510), the package substrate (110, 210, 510) may comprise a core structure (120, 220, 520); a first embedded passive substrate (EPS) layer (130, 230, 530) directly attached to a first side of the core structure (120, 220, 520), wherein a first passive device is embedded in the first layer; a second EPS layer directly attached to a second side of the core structure (120, 220, 520) opposite the first side of the core structure (120, 220, 520), wherein a second passive device is embedded in the second EPS layer; a first build-up layer directly attached to the first layer opposite the core structure (120, 220, 520); and a second build-up layer directly attached to the second EPS layer opposite the core structure (120, 220, 520). As discussed above, the core structure (120, 220, 520) may comprise a first core layer (e.g., a single core layer) or may also include one or more additional core layers such as a second core layer and a center dielectric disposed between the first core layer and the second core layer.

It will be appreciated that the core layers may be formed from any suitable material, such as, copper clad laminate (CCL) core with 1, 2, or more cores and may also include 2 or more prepreg layers. The core thickness may range from 100 um to 1.2 mm in thickness. The EPS layers may be in the range of 10 um to 1.2 mm in thickness. The build-up layers (e.g., prepreg, Ajinomoto build-up film (ABF), resin coated copper (RCC) build-up film, etc.) may be in the range of 15 um to 45 um in thickness.

It will be appreciated that the various aspects disclosed include provide various technical advantages. For example, multicore substrate examples herein provide for closer connectivity to semiconductor dies than obtainable from device passive substrates, land side capacitors, or die side capacitors. Additionally, the various aspects provide for better pitch placement than non-pre-packaged/device components, high density configurations, structural symmetry, and better mechanical stability. Additionally, since the package substrate includes embedded passive devices, area on the land side (external connection side) is not used and ball grid array depopulation is not needed for land side passive devices.

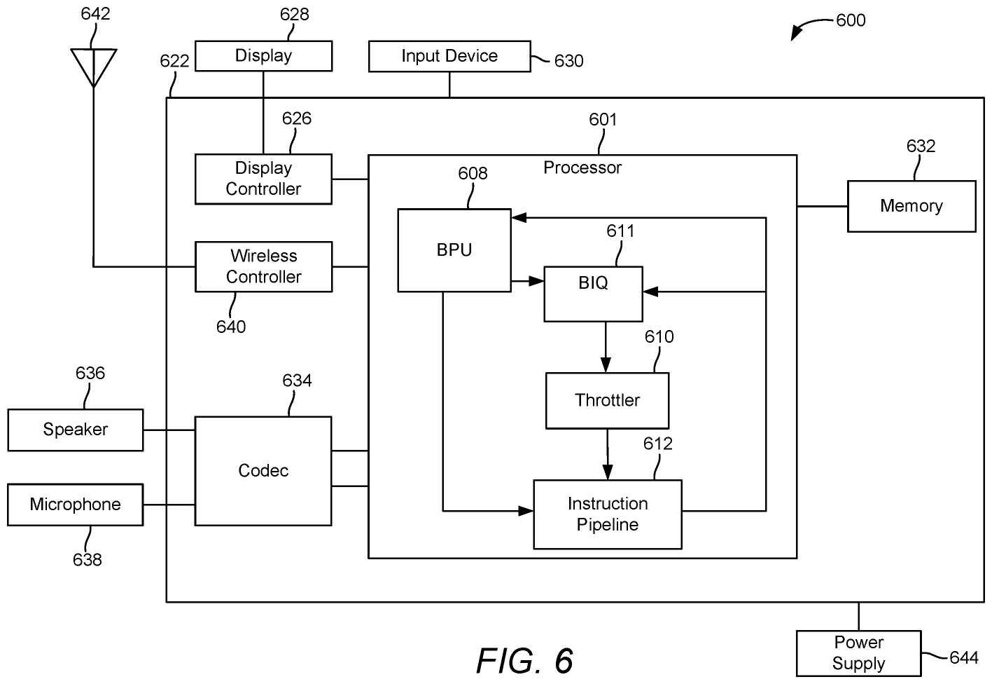

FIG. 6 illustrates an exemplary mobile device in accordance with at least one aspect of the disclosure. Referring now to FIG. 6, a block diagram of a mobile device that is configured according to exemplary aspects is depicted and generally designated mobile device 600. In some aspects, mobile device 600 may be configured as a wireless communication device. As shown, mobile device 600 includes processor 601, which may be configured to implement the methods described herein in some aspects. Processor 601 is shown to comprise instruction pipeline 612, buffer processing unit (BPU) 608, branch instruction queue (BIQ) 611, and throttler 610 as is well known in the art. Other well-known details (e.g., counters, entries, confidence fields, weighted sum, comparator, etc.) of these blocks have been omitted from this view of processor 601 for the sake of clarity.

Processor 601 may be communicatively coupled to memory 632 over a link, which may be a die-to-die or chip-to-chip link. Mobile device 600 also include display 628 and display controller 626, with display controller 626 coupled to processor 601 and to display 628.

In some aspects, FIG. 6 may include coder/decoder (CODEC) 634 (e.g., an audio and/or voice CODEC) coupled to processor 601; speaker 636 and microphone 638 coupled to CODEC 634; and wireless controller 640 (which may include a modem) coupled to wireless antenna 642 and to processor 601.

In a particular aspect, where one or more of the above-mentioned blocks are present, processor 601, display controller 626, memory 632, CODEC 634, and wireless controller 640 can be included in a system-in-package or system-on-chip device 622. Input device 630 (e.g., physical or virtual keyboard), power supply 644 (e.g., battery), display 628, input device 630, speaker 636, microphone 638, wireless antenna 642, and power supply 644 may be external to system-on-chip device 622 and may be coupled to a component of system-on-chip device 622, such as an interface or a controller.

It should be noted that although FIG. 6 depicts a mobile device, processor 601 and memory 632 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

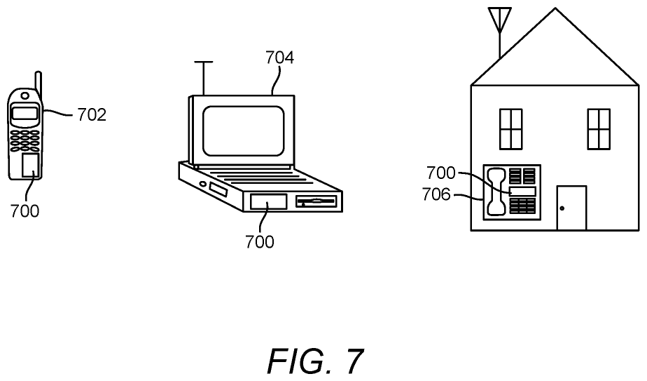

FIG. 7 illustrates various electronic devices that may be integrated with any of the aforementioned integrated device, semiconductor device, integrated circuit, die, interposer, package, or package-on-package (PoP) in accordance with at least one aspect of the disclosure. For example, a mobile phone device 702, a laptop computer device 704, and a fixed location terminal device 706 may include an integrated device 700 as described herein. The integrated device 700 may be, for example, any of the integrated circuits, dies, integrated devices, integrated device packages, integrated circuit devices, device packages, integrated circuit (IC) packages, package-on-package devices described herein. The devices 702, 704, 706 illustrated in FIG. 7 are merely exemplary. Other electronic devices may also feature the integrated device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device comprising means for performing the respective actions of this method. For example, in one aspect, an apparatus may comprise means for insulating (e.g., a core layer); first means for embedding (e.g., first layer) directly attached to a first side of the means for insulating; second means for embedding (e.g., second layer) directly attached to a second side of the means for insulating, the second side of the means for insulating opposite the first side of the means for insulating; a first means for support (e.g., first build-up layer) directly attached to the first means for embedding opposite the means for insulating; a second means for support (e.g., second build-up layer) directly attached to the second means for embedding opposite the means for insulating; a first passive device in the first means for embedding; and a second passive device in the second means for embedding. It will be appreciated that the aforementioned aspects are merely provided as examples and the various aspects claimed are not limited to the specific references and/or illustrations cited as examples.

One or more of the components, processes, features, and/or functions illustrated in FIGS. 1-7 may be rearranged and/or combined into a single component, process, feature, or function or incorporated in several components, processes, or functions. Additional elements, components, processes, and/or functions may also be added without departing from the disclosure. It should also be noted that FIGS. 1-7 and its corresponding description in the present disclosure is not limited to dies and/or ICs. In some implementations, FIGS. 1-6 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of a device, such as a die, is the part of the device that contains the active components of the device (e.g. transistors, resistors, capacitors, inductors etc.), which perform the operation or function of the device. The backside of a device is the side of the device opposite the active side. As used herein, a metallization structures may include metal layers, vias, pads, or traces with dielectric between, such as a redistribution layer or RDL).

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wire line connection, or other connection, regardless of whether satellite signal reception, assistance data reception, and/or position-related processing occurs at the device or at the other device. In addition, these terms are intended to include all devices, including wireless and wire line communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wire line phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (Wi-Fi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage, or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer, or an electronic circuit. In at least one aspect, some or a plurality of the most important method actions can be performed by such an apparatus.

Further, it will be appreciated that in some examples, an individual action can be subdivided into a plurality of sub-actions or contain a plurality of sub-actions. Such sub-actions can be contained in the disclosure of the individual action and be part of the disclosure of the individual action.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses claims should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:

Clause 1. A package comprising: a core layer; a first layer directly attached to a first side of the core layer, wherein a first device is embedded in the first layer; a second layer directly attached to a second side of the core layer opposite the first side, wherein a second passive device is embedded in the second layer; a first build-up layer directly attached to the first layer opposite the core layer; and a second build-up layer directly attached to the second layer opposite the core layer.

Clause 2. The package of clause 1, further comprising a semiconductor die on the first build-up layer opposite the first layer.

Clause 3. The package of any of clauses 1 to 2, further comprising a plurality of solder balls on the second build-up layer opposite the second layer.

Clause 4. The package of any of clauses 1 to 3, wherein the first passive device and the second passive device are symmetrically located on opposite sides of the core layer.

Clause 5. The package of any of clauses 1 to 4, wherein the core layer comprises is a plurality of laminate layers.

Clause 6. The package of any of clauses 1 to 5, wherein the first layer comprises a plurality of dielectric layers.

Clause 7. The package of any of clauses 1 to 6, wherein the second layer comprises a plurality of dielectric layers.

Clause 8. The package of any of clauses 1 to 7, wherein the first build-up layer comprises a plurality of prepreg layers.

Clause 9. The package of any of clauses 1 to 8, wherein the second build-up layer comprises a plurality of prepreg layers.

Clause 10. The package of any of clauses 1 to 9, wherein the package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

Clause 11. An apparatus comprising a package substrate, the package substrate comprising: a core structure; a first embedded passive substrate (EPS) layer directly attached to a first side of the core structure, wherein a first passive device is embedded in the first layer; a second EPS layer directly attached to a second side of the core structure opposite the first side of the core structure, wherein a second passive device is embedded in the second EPS layer; a first build-up layer directly attached to the first layer opposite the core structure; and a second build-up layer directly attached to the second EPS layer opposite the core structure.

Clause 12. The apparatus of clause 11, wherein the core structure comprises: a first core layer.

Clause 13. The apparatus of clause 12, wherein the core structure further comprises: a second core layer; and a center dielectric disposed between the first core layer and the second core layer; Clause 14. The apparatus of any of clauses 11 to 13, further comprising a semiconductor die coupled to the first build-up layer of the package substrate opposite the first EPS layer.

Clause 15. The apparatus of any of clauses 11 to 14, wherein the first passive device and the second passive device are symmetrically located on opposite sides of the core structure.

Clause 16. The apparatus of any of clauses 11 to 15, wherein the first EPS layer comprises: a first plurality of dielectric layers.

Clause 17. The apparatus of clause 16, wherein the first EPS layer further comprises: a first EPS core disposed between two dielectric layers of the first plurality of dielectric layers, wherein the first passive device is disposed in a cavity of in the first EPS core.

Clause 18. The apparatus of clause 17, wherein the second EPS layer comprises: a second plurality of dielectric layers.

Clause 19. The apparatus of clause 18, wherein the second EPS layer further comprises: a second EPS core disposed between two dielectric layers of the second plurality of dielectric layers, wherein the second passive device is disposed in a cavity in the second EPS core.

Clause 20. The apparatus of any of clauses 11 to 19, wherein the first build-up layer comprises one or more metallization structures.

Clause 21. The apparatus of clause 20, wherein the first build-up layer comprises a plurality of prepreg layers, Ajinomoto build-up film or resin coated copper build-up film.

Clause 22. The apparatus of any of clauses 20 to 21, wherein the second build-up layer comprises a plurality of prepreg layers, Ajinomoto build-up film or resin coated copper build-up film.

Clause 23. The apparatus of any of clauses 11 to 22, further comprising: a first plated through hole (PTH) disposed through the core structure, the first layer and the second layer, wherein the first PTH is coupled to the first build-up layer and to the second build-up layer.

Clause 24. The apparatus of clause 23, further comprising: a second PTH disposed through the core structure the first layer and the second layer, wherein the second PTH is coupled to the first build-up layer and to the second build-up layer, and wherein the first passive device and the second passive device are each disposed between the first PTH and the second PTH.

Clause 25. The apparatus of any of clauses 11 to 24, further comprising: a first plurality of vias disposed between the first passive device and the first build-up layer and configured to electrically coupled the first passive device to the first build-up layer.

Clause 26. The apparatus of clause 25, further comprising: a second plurality of vias disposed between the second passive device and the second build-up layer and configured to electrically coupled the second passive device to the second build-up layer.

Clause 27. The apparatus of any of clauses 11 to 26, wherein the first build-up layer comprises a first metallization structure configured to provide electrical coupling between a die disposed on the first build-up layer and the first passive device, and wherein the second build-up layer comprises a second metallization structure configured to provide electrical coupling between the second passive device and at least one solder ball, coupled to the second build-up layer.

Clause 28. The apparatus of any of clauses 11 to 27, wherein the apparatus is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

Clause 29. A method for manufacturing a package, the method comprising: providing a core layer; forming a first layer directly on a first side of the core layer; forming a second layer directly on a second side of the core layer, the second side of the core layer opposite the first side of the core layer; embedding a first passive device in the first layer; embedding a second passive device in the second layer; forming a first build-up layer directly on the first layer opposite the core layer; and forming a second build-up layer directly on the second layer opposite the core layer.

Clause 30. The method of clause 29, wherein embedding the first passive device in the first layer further comprises: providing a first embedded passive substrate (EPS) core; forming a first cavity in the first EPS core; placing the first passive device in the first cavity; and depositing a first dielectric over the first EPS core, the first passive device and the first cavity, and wherein embedding the second passive device in the second layer further comprises: providing a second EPS core; forming a second cavity in the second EPS core; placing the second passive device in the second cavity; and depositing a second dielectric over the second EPS core, the second passive device and the second cavity.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A package comprising:
a core layer;
a first layer directly attached to a first side of the core layer, wherein a first device is embedded in the first layer;
a second layer directly attached to a second side of the core layer opposite the first side, wherein a second passive device is embedded in the second layer;
a first build-up layer directly attached to the first layer opposite the core layer; and
a second build-up layer directly attached to the second layer opposite the core layer.

2. The package of claim 1, further comprising a semiconductor die on the first build-up layer opposite the first layer.

3. The package of claim 1, further comprising a plurality of solder balls on the second build-up layer opposite the second layer.

4. The package of claim 1, wherein the first passive device and the second passive device are symmetrically located on opposite sides of the core layer.

5. The package of claim 1, wherein the core layer comprises is a plurality of laminate layers.

6. The package of claim 1, wherein the first layer comprises a plurality of dielectric layers.

7. The package of claim 1, wherein the second layer comprises a plurality of dielectric layers.

8. The package of claim 1, wherein the first build-up layer comprises a plurality of prepreg layers.

9. The package of claim 1, wherein the second build-up layer comprises a plurality of prepreg layers.

10. The package of claim 1, wherein the package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

11. An apparatus comprising a package substrate, the package substrate comprising:
a core structure;
a first embedded passive substrate (EPS) layer directly attached to a first side of the core structure, wherein a first passive device is embedded in the first layer;
a second EPS layer directly attached to a second side of the core structure opposite the first side of the core structure, wherein a second passive device is embedded in the second EPS layer;
a first build-up layer directly attached to the first layer opposite the core structure; and
a second build-up layer directly attached to the second EPS layer opposite the core structure.

12. The apparatus of claim 11, wherein the core structure comprises:
a first core layer.

13. The apparatus of claim 12, wherein the core structure further comprises:
a second core layer; and
a center dielectric disposed between the first core layer and the second core layer;

14. The apparatus of claim 11, further comprising a semiconductor die coupled to the first build-up layer of the package substrate opposite the first EPS layer.

15. The apparatus of claim 11, wherein the first passive device and the second passive device are symmetrically located on opposite sides of the core structure.

16. The apparatus of claim 11, wherein the first EPS layer comprises:
a first plurality of dielectric layers.

17. The apparatus of claim 16, wherein the first EPS layer further comprises:
a first EPS core disposed between two dielectric layers of the first plurality of dielectric layers, wherein the first passive device is disposed in a cavity of in the first EPS core.

18. The apparatus of claim 17, wherein the second EPS layer comprises:
a second plurality of dielectric layers.

19. The apparatus of claim 18, wherein the second EPS layer further comprises:
a second EPS core disposed between two dielectric layers of the second plurality of dielectric layers, wherein the second passive device is disposed in a cavity in the second EPS core.

20. The apparatus of claim 11, wherein the first build-up layer comprises one or more metallization structures.

21. The apparatus of claim 20, wherein the first build-up layer comprises a plurality of prepreg layers, Ajinomoto build-up film or resin coated copper build-up film.

22. The apparatus of claim 20, wherein the second build-up layer comprises a plurality of prepreg layers, Ajinomoto build-up film or resin coated copper build-up film.

23. The apparatus of claim 11, further comprising:
a first plated through hole (PTH) disposed through the core structure, the first layer and the second layer, wherein the first PTH is coupled to the first build-up layer and to the second build-up layer.

24. The apparatus of claim 23, further comprising:
a second PTH disposed through the core structure the first layer and the second layer, wherein the second PTH is coupled to the first build-up layer and to the second build-up layer, and
wherein the first passive device and the second passive device are each disposed between the first PTH and the second PTH.

25. The apparatus of claim 11, further comprising:
a first plurality of vias disposed between the first passive device and the first build-up layer and configured to electrically coupled the first passive device to the first build-up layer.

26. The apparatus of claim 25, further comprising:
a second plurality of vias disposed between the second passive device and the second build-up layer and configured to electrically coupled the second passive device to the second build-up layer.

27. The apparatus of claim 11, wherein the first build-up layer comprises a first metallization structure configured to provide electrical coupling between a die disposed on the first build-up layer and the first passive device, and
wherein the second build-up layer comprises a second metallization structure configured to provide electrical coupling between the second passive device and at least one solder ball, coupled to the second build-up layer.

28. The apparatus of claim 11, wherein the apparatus is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

29. A method for manufacturing a package, the method comprising:
providing a core layer;
forming a first layer directly on a first side of the core layer;
forming a second layer directly on a second side of the core layer, the second side of the core layer opposite the first side of the core layer;
embedding a first passive device in the first layer;
embedding a second passive device in the second layer;
forming a first build-up layer directly on the first layer opposite the core layer; and
forming a second build-up layer directly on the second layer opposite the core layer.

30. The method of claim 29, wherein embedding the first passive device in the first layer further comprises:
providing a first embedded passive substrate (EPS) core;
forming a first cavity in the first EPS core;
placing the first passive device in the first cavity; and
depositing a first dielectric over the first EPS core, the first passive device and the first cavity,
and
wherein embedding the second passive device in the second layer further comprises:
providing a second EPS core;
forming a second cavity in the second EPS core;
placing the second passive device in the second cavity; and
depositing a second dielectric over the second EPS core, the second passive device and the second cavity.
